(19) United States
(12) Patent Application Publication
(10) Pub. No.: US 2018/0108540 A1
(43) Pub. Date: Apr. 19, 2018

(54) METHOD OF FORMING AN INTERPOSER AND A METHOD OF MANUFACTURING A SEMICONDUCTOR PACKAGE INCLUDING THE SAME

(71) Applicant: SAMSUNG ELECTRONICS CO., LTD., Suwon-si (KR)

(72) Inventors: Jae-Hyun Phee, Incheon (KR); Ho-Jin Lee, Seoul (KR); Taeseong Kim, Suwon-si (KR); Kwangjin Moon, Hwaseong-si (KR); Jin Ho An, Seoul (KR); Naein Lee, Seoul (KR)

(21) Appl. No.: 15/636,849

(22) Filed: Jun. 29, 2017

(30) Foreign Application Priority Data
Oct. 13, 2016 (KR) 10-2016-0132889

(51) Int. Cl. H01L 21/48; H01L 23/498; H01L 21/683; H01L 23/64; H01L 23/00; H05K 3/40; H05K 1/16

(52) U.S. Cl. CPC H01L 21/486; H01L 23/49827; H01L 23/49811; H05K 1/162; H01L 23/642; H01L 24/05; H05K 3/4038; H01L 21/6835

(57) ABSTRACT

A method of manufacturing a semiconductor package including forming a photoresist pattern on a first surface of an interposer substrate. The interposer substrate includes an electrode zone and a scribe line zone. The interposer substrate is etched using the photoresist pattern as a mask to form a first opening and a second opening respectively on the electrode zone and the scribe line zone. An insulation layer and a conductive layer are formed on the first surface of the interposer substrate. A width of the second opening is smaller than a width of the first opening. The insulation layer contacts each of the first surface of the interposer substrate, an inner surface of the first opening, and an inner surface of the second opening.

### CROSS-REFERENCE TO RELATED APPLICATION

This application claims priority under 35 U.S.C. § 119 to Korean Patent Application 10-2016-0132889 filed on Oct. 13, 2016 in the Korean Intellectual Property Office, the disclosure of which is incorporated by reference herein in its entirety.

### TECHNICAL FIELD

Exemplary embodiments of the present inventive concept relate to an interposer, and more particularly, to a method of manufacturing a semiconductor package including the same.

### DISCUSSION OF RELATED ART

A plurality of semiconductor processes may be performed on a wafer in order to form a plurality of semiconductor chips. A packaging process may be performed on the wafer. The packaging process may mount each of the semiconductor chips on a printed circuit board (PCB). Thus, a semiconductor package may be manufactured.

Multi-dimensional semiconductor packages, such as 2.5- and 3-dimensional packages have been developed. Each of the 2.5- and 3-dimensional packages may include a plurality of semiconductor chips. The semiconductor chips may be vertically mounted in the 2.5- and 3-dimensional packages. Through silicon via (TSV) technology may be used to form a vertical electrical connection passing through a substrate, a die, or an interposer.

### SUMMARY

Exemplary embodiments of the present inventive concept provide a method of forming an interposer, and more particularly a method of manufacturing a semiconductor package including the same. The method of manufacturing the semiconductor package including the interposer may have increased electrical characteristics and a relatively high process yield.

Exemplary embodiments of the present inventive concept provides a method of manufacturing a semiconductor package. The method includes forming a photoresist pattern on a first surface of an interposer substrate. The interposer substrate includes an electrode zone and a scribe line zone. The interposer substrate is etched using the photoresist pattern as a mask to form a first opening and a second opening respectively on the electrode zone and the scribe line zone. An insulation layer and a conductive layer are formed on the first surface of the interposer substrate. A width of the second opening is smaller than a width of the first opening. The insulation layer contacts each of the first surface of the interposer substrate, an inner surface of the first opening, and an inner surface of the second opening.

Exemplary embodiments of the present inventive concept provide a method of forming an interposer. The method includes forming a through electrode and an alignment key structure in a first region and a second region of an interposer substrate, respectively. Forming the through electrode and the alignment key structure includes forming a photoresist pattern on a first surface of the interposer substrate. The photoresist pattern is in contact with the first surface. The interposer substrate is etched using the photoresist pattern as a mask to form a first opening and a second opening. The through electrode is disposed in the first opening. The alignment key structure is disposed in the second opening. An insulation layer, a first conductive layer, and a second conductive layer are formed on the first surface of the interposer substrate. The insulation layer contacts each of the first surface of the interposer substrate, an inner surface of the first opening, and an inner surface of the second opening.

Exemplary embodiments of the present inventive concept provide a method of manufacturing a semiconductor package. The method includes forming a photoresist pattern on an interposer substrate. The interposer substrate includes a first area and a second area. A first opening is formed on the first area and a second opening is formed on the second area by etching the interposer substrate using the photoresist pattern as a mask. An insulation layer is formed on the interposer substrate. The insulation layer contacts each of the interposer substrate, the first opening, and the second opening.

### BRIEF DESCRIPTION OF THE DRAWINGS

These and/or other aspects will become more apparent and more readily appreciated from the following description of the exemplary embodiments, taken in conjunction with the accompanying drawings, in which:

FIG. 1 is a plan view illustrating an interposer wafer for manufacturing a semiconductor package according to an exemplary embodiment of the present inventive concept;

FIG. 2 is an enlarged view of Section A of FIG. 1 according to an exemplary embodiment of the present inventive concept;

FIG. 3 is a plan view illustrating shapes of alignment keys according to an exemplary embodiment of the present inventive concept;

FIG. 4 is a cross-sectional view illustrating a semiconductor package including an interposer according to an exemplary embodiment of the present inventive concept;

FIG. 5 is a plan view illustrating a method of forming an interposer according to an exemplary embodiment of the present inventive concept; and

FIGS. 6 to 17 are cross-sectional views taken along lines I-I′ and II-II′ of FIG. 5 according to an exemplary embodiment of the present inventive concept.

### DETAILED DESCRIPTION OF EMBODIMENTS

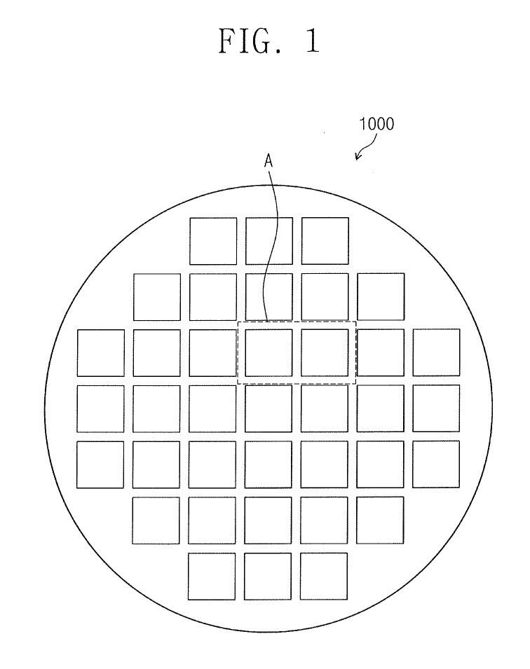

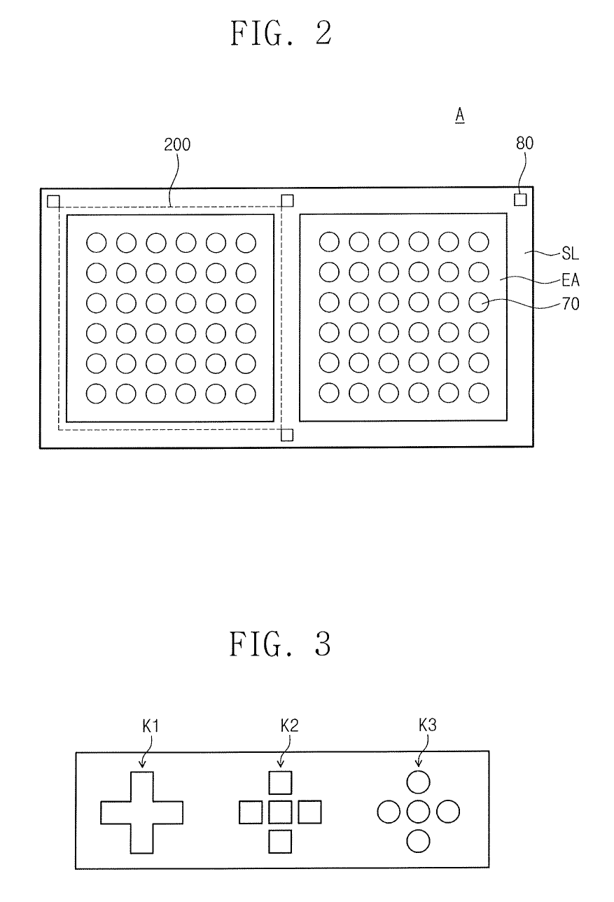

FIG. 1 is a plan view illustrating an interposer wafer for manufacturing a semiconductor package according to an exemplary embodiment of the present inventive concept. FIG. 2 is an enlarged view of Section A of FIG. 1 according to an exemplary embodiment of the present inventive concept. FIG. 3 is a plan view of shapes of alignment keys according to an exemplary embodiment of the present inventive concept.

Referring to FIGS. 1 and 2, an interposer wafer 1000 may include a plurality of electrode zones EA and a scribe line zone SL. The scribe line zone SL may separate the plurality of electrode zones EA from each other. The electrode zones EA may correspond to a region where through electrodes 70 are formed. The scribe line zone SL may be a region for dicing the interposer wafer 1000 into interposers 200, for example, after a process for manufacturing the interposer wafer 1000 is performed. An alignment key structure 80 may be formed on the scribe line zone SL.

The alignment key structure 80 may have a shape similar to a contact shape or a trench shape. Referring to FIG. 3, the alignment key structure 80 may have variously shaped patterns K1, K2, and K3. The alignment key structure 80 may be a local alignment key, a global alignment key, a registration alignment key, an overlay alignment key, or a measurement key.

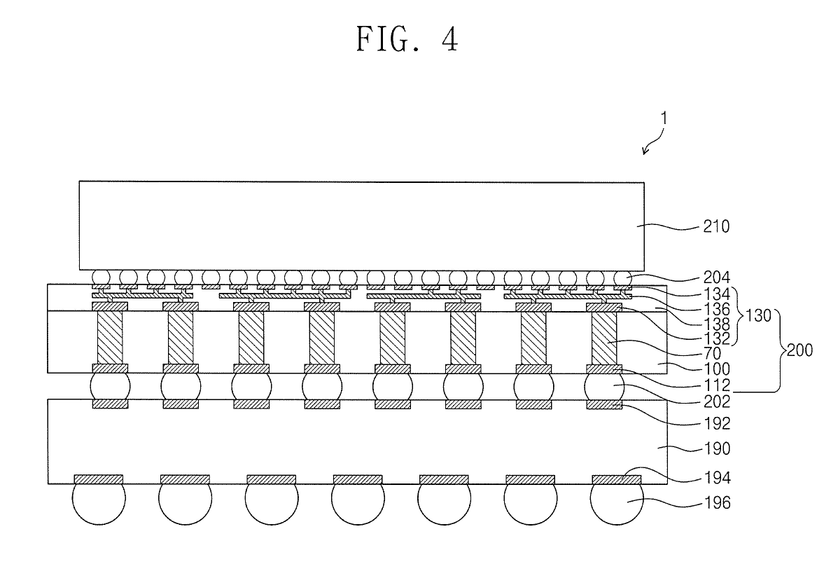

FIG. 4 is a cross-sectional view illustrating a semiconductor package including an interposer according to an exemplary embodiment of the present inventive concept.

Referring to FIG. 4, a semiconductor package 1 may include a lower base substrate 190, an interposer 200, and a semiconductor chip 210. The interposer 200 may be disposed on the lower base substrate 190. The semiconductor chip 210 may be disposed on the interposer 200.

The lower base substrate 190 may include glass, ceramic, or plastic. The lower base substrate 190 may be a substrate for a semiconductor package. For example, the lower base substrate 190 may be a printed circuit board, a ceramic substrate, or a tape substrate. The lower base substrate 190 may include first pads 192 and second pads 194. The first pads 192 may be positioned on an upper surface of the lower base substrate 190. The second pads 194 may be positioned on a lower surface of the lower base substrate 190. The first pads 192 may be electrically connected to the second pads 194, for example, through electrical lines positioned in the lower base substrate 190. The first pads 192 of the lower base substrate 190 may be electrically and/or physically connected to lower interconnect members 202.

The second pads 194 of the lower base substrate 190 may be electrically and/or physically connected to external interconnect members 196. The lower base substrate 190 may be electrically connected to an external device, for example, through the external interconnect members 196. For example, the external interconnect members 196 may be a solder ball. Alternatively, the external interconnect members 196 may have a flip-chip interconnect structure. The flip-chip interconnect structure may have a grid array such as a pin grid array, a ball grid array, or a land grid array.

The interposer 200 may be disposed on the lower base substrate 190. The interposer 200 may include an interposer substrate 100, interposer lower pads 112, through electrodes 70, and a routing layer 130. The interposer lower pads 112 may be electrically and/or physically connected to the lower interconnect members 202. The interposer 200 may be electrically connected to the lower base substrate 190, for example, through the lower interconnect members 202.

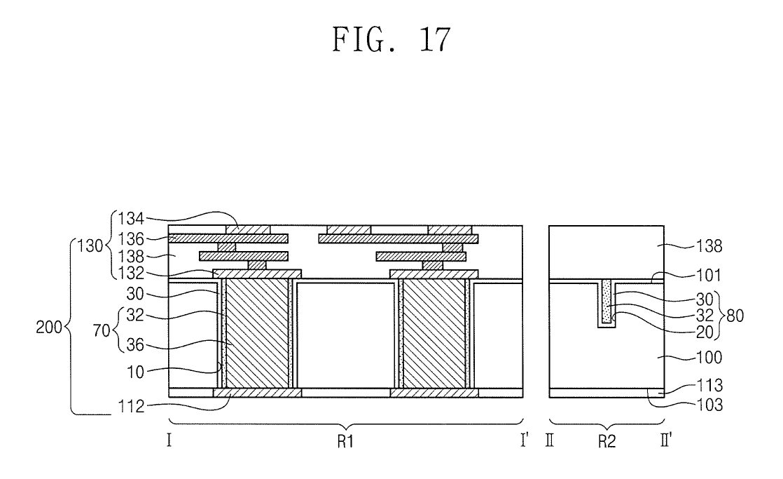

The interposer lower pads 112 may be disposed on a lower surface of the interposer substrate 100. The through electrodes 70 may penetrate the interposer substrate 100. The interposer lower pads 112 may be electrically connected to the routing layer 130, for example, thorough the through electrodes 70. Referring to FIG. 17, the interposer substrate 100 may be disposed on the lower surface of the interposer substrate 100 with an insulation layer. The interposer lower pads 112 may be exposed through the insulation layer.

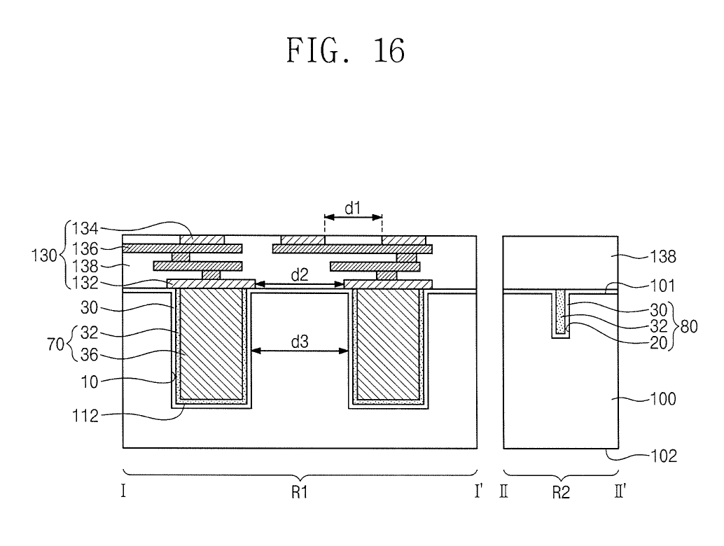

The routing layer 130 may be disposed on the interposer substrate 100. The routing layer 130 may include lower pads 132, an interlayer dielectric layer 138, electrical line patterns 136, and upper pads 134. The routing layer 130 will be described in more detail below with reference to FIG. 16. The upper pads 134 of the routing layer 130 may be electrically and/or physically connected to upper interconnect members 204.

The interposer 200 may be disposed with a semiconductor chip 210. Alternatively, the interposer 200 may be disposed with a plurality of semiconductor chips 210. The semiconductor chip 210 may be a semiconductor logic chip or a semiconductor memory chip. For example, the semiconductor chip 210 may include one or more of system LSIs (large scale integrations), logic circuits, image sensors such as CIS (CMOS image sensor), MEMS (microelectromechanical system), and memory devices such as Flash memory, DRAM, SRAM, EEPROM, PRAM, MRAM, ReRAM, HBM (high bandwidth memory), or HMC (hybrid memory cubic).

The upper interconnect members 204 may be positioned on a lower surface of the semiconductor chip 210. The semiconductor chip 210 may be electrically connected to the routing layer 130 of the interposer 200, for example, through the upper interconnect members 204. For example, the upper interconnect members 204 may be a solder ball or a bonding wire. The upper interconnect members 204 may have a flip-chip interconnect structure having a grid array such as a pin grid ball array, a ball grid array, or a land grid array.

A method of forming an interposer according to an exemplary embodiment of the present inventive concept will be described in more detail below.

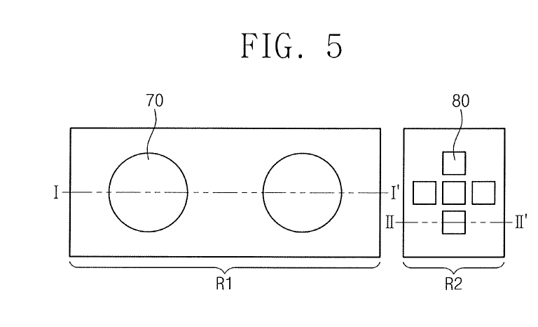

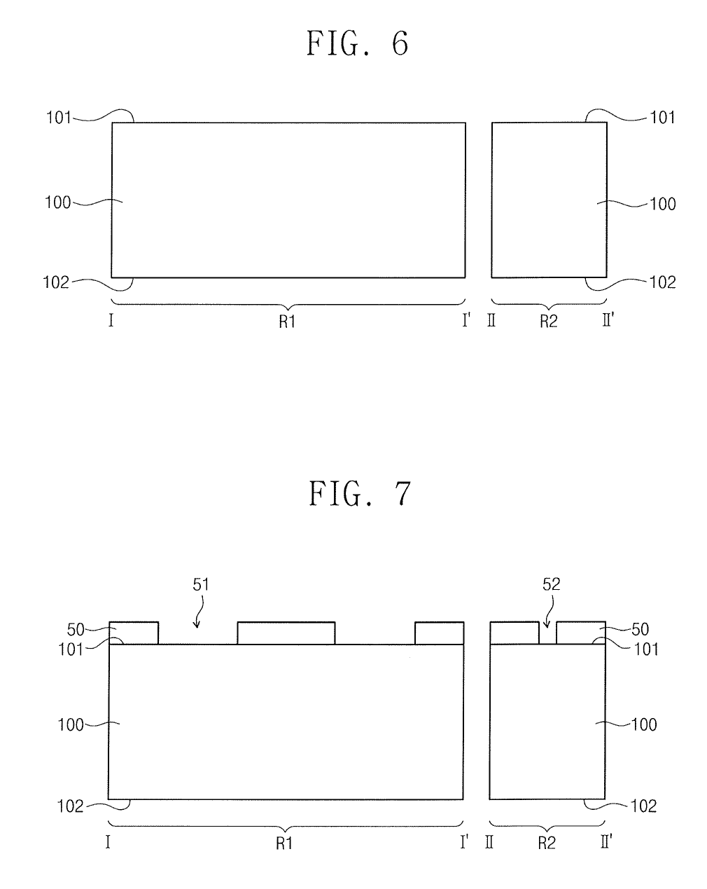

FIG. 5 is a plan view illustrating a method of forming an interposer according to an exemplary embodiment of the present inventive concept. FIGS. 6 to 17 are cross-sectional views taken along lines I-I′ and II-II′ of FIG. 5 according to an exemplary embodiment of the present inventive concept.

Referring to FIGS. 5 and 6, an interposer substrate 100 may include a first region R1 and a second region R2. The first region R1 may be a portion of the electrode zone EA of FIG. 1. The second region R2 may be a portion of the scribe line zone SL of FIG. 1. The interposer substrate 100 may include an upper surface 101 and a lower surface 102. The upper surface 101 and the lower surface 102 may face each other.

The interposer substrate 100 may include a semiconductor or an insulating material. The insulating material may include silicon, germanium, silicon-germanium (SiGe), gallium-arsenic (GaAs), glass, or ceramic.

Referring to FIGS. 5 and 7, a photoresist pattern 50 may be formed on the upper surface 101 of the interposer substrate 100. According to an embodiment of the present inventive concept, the photoresist pattern 50 may be directly formed on the upper surface 101 of the interposer substrate 100. Accordingly, the photoresist pattern 50 may be in direct contact with the upper surface 101 of the interposer substrate 100. Thus, a hardmask might not be separately interposed between the interposer substrate 100 and the photoresist pattern 50. The hardmask may include a silicon oxide layer and/or a silicon nitride layer formed as an etch mask for an etching process.

The interposer substrate 100 may be provided with the photoresist pattern 50 in direct contact with the upper surface 101 thereof. Thus, the photoresist pattern 50 may be an etch mask when an etching process is performed, for example, to etch the interposer substrate 100 as described in more detail below. The interposer substrate 100 may have a reduced occurrence or absence of undercuts.

The photoresist pattern 50 may include a third opening 51 and a fourth opening 52. The third opening 51 may expose the upper surface 101 of the first region R1. The fourth opening 52 may expose the upper surface 101 of the second region R2. The fourth opening 52 may have a width less than a width of the third opening 51.

According to an exemplary embodiment of the present inventive concept, the fourth opening 52 may have various shapes such as a circle, an oval, a triangle, a rectangle, or a cross.

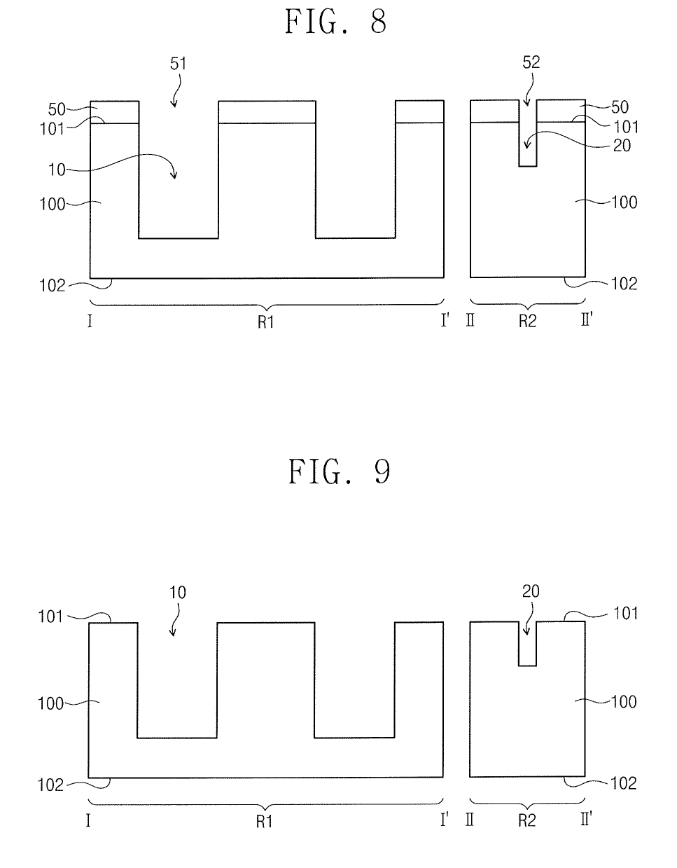

Referring to FIGS. 5 and 8, an etching process may be performed on the upper surface 101 of the interposer substrate 100 exposed through the photoresist pattern 50. Thus, a first opening 10 and a second opening 20 may be formed. On the first region R1, the first opening 10 may have a hole shape or a trench shape. The hole shape or the trench shape may extend toward the lower surface 102 from the upper surface 101 of the interposer substrate 100. On the second region R2, the second opening 20 may have a hole shape or a trench shape. The hole shape or the trench shape may extend toward the lower surface 102 from the upper surface 101 of the interposer substrate 100. The shapes of the first and second openings 10 and 20, however, are not limited thereto. The first and second openings 10 and 20 may have, for example, a pillar shape having a diameter substantially the same along a height of the pillar shape from the upper surface 101 to the lower surface 102 of the interposer substrate 100. The first and second openings 10 and 20 may have a tapered shape having a gradually changing diameter gradually (e.g., a diameter decreasing in a direction toward the lower surface 102 of the interposer substrate 100).

The second opening 20 may have a width less than a width of the first opening 10. For example, the width of the first opening 10 may be in the range from several to hundreds of micrometers. The width of the second opening 20 may be in the range from several to tens of nanometers.

A single etching process may be performed to form the first and second openings 10 and 20 at substantially the same time. The second opening 20 may have a depth less than a depth of the first opening 10, for example, due to a difference between a width of the third opening 51 and a width of the fourth opening 52. A dry etching method or a wet etching method may be performed, for example, to etch the upper surface 101 of the interposer substrate 100 exposed through the photoresist pattern 50. For example, a dry etching method may be performed as the etching process.

According to an exemplary embodiment of the present inventive concept, a plurality of fourth openings 52 may be formed on the second region R2. Thus, a plurality of second openings 20 may be formed. A plurality of second openings 20 may be densely arranged in various patterns. For example, referring to FIG. 3, the second openings 20 may be arranged in a cross shape pattern (K2 or K3).

Referring to FIGS. 5 and 9, the photoresist pattern 50 may be removed. The removal of the photoresist pattern 50 may expose the upper surface 101 of the interposer substrate 100. For example, an ashing process may be performed to remove the photoresist pattern 50.

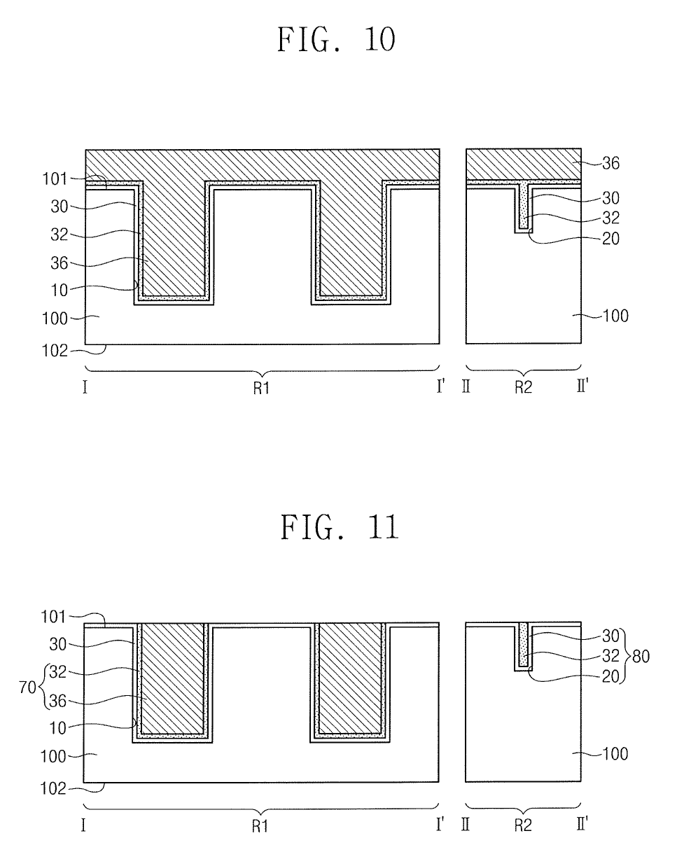

Referring to FIGS. 5 and 10, an insulation layer 30 may be conformally formed on the interposer substrate 100. On the first region R1, the insulation layer 30 may cover the upper surface 101 of the interposer substrate 100. The insulation layer 30 may also cover an inner surface of the first opening 10. On the second region R2, the insulation layer 30 may cover the upper surface 101 of the interposer substrate 100. The insulation layer 30 may also cover an inner surface of the second opening 20. The insulation layer 30 may include a silicon oxide layer, a silicon oxynitride layer, a silicon nitride layer, or a combination thereof.

The insulation layer 30 may be in direct contact with each of the upper surface 101 of the interposer substrate 100, the inner surface of the first opening 10, and the inner surface of the second opening 20. As the insulation layer 30 is in direct contact with the upper surface 101 of the interposer substrate 100, the inner surface of the first opening 10, and the inner surface of the second opening 20; surface defects produced on the interposer substrate 100 during the formation of the first and second openings 10 and 20 may be reduced or prevented. The surface defects produced on the interposer substrate 100 may be a dangling bond.

A first conductive layer 32 may be conformally formed on the insulation layer 30. On the first region R1, the first conductive layer 32 may partially fill the first opening 10 in which the insulation layer 30 is formed.

On the second region R2, the first conductive layer 32 may fill the second opening 20 in which the insulation layer 30 is formed. According to an exemplary embodiment of the present inventive concept, a sum of thicknesses of the insulation layer 30 and the first conductive layer 32 may be greater than half the width of the second opening 20.

The first conductive layer 32 may include a metal nitride. For example, the metal nitride may include titanium (Ti), titanium nitride (TiN), tantalum (Ta), or tantalum nitride (TaN). The first conductive layer 32 may reduce or prevent a conductive material from diffusing into the interposer substrate 100. The conductive material may be a constituent of a second conductive material 35 formed in another process.

A second conductive layer 36 may be formed on the first conductive layer 32. On the first region R1, the second conductive layer 36 may fill the first opening 10 in which the insulation layer 30 and the first conductive layer 32 are formed. On the second region R2, the second conductive layer 36 may be disposed on an upper surface of the first conductive layer 32. Thus, the second conductive layer 36 might not completely fill the second opening 20.

The second conductive layer 36 may include a metallic material. For example, the second conductive layer 36 may include copper (Cu). An electroplating process may be used to form the second conductive layer 36.

Referring to FIGS. 5 and 11, a polishing process may be performed on the interposer substrate 100. The polishing process may be performed until an upper surface of the insulation layer 30 is exposed. The polishing process may remove portions of the second conductive layer 36 and the first conductive layer 32. Thus, the insulation layer 30 may be partially exposed.

A chemical mechanical polishing (CMP) may be used to perform the polishing process. The insulation layer 30 may be a polishing stop layer. On the first region R1, the second conductive layer 36 may have an upper surface positioned above the upper surface 101 of the interposer substrate 100. Thus, a routing layer 130 of FIG. 16 may be electrically and/or physically connected with the upper surface of the second conductive layer 36 in an additional process. For example, on the first region R1, the upper surface of the second conductive layer 36 may be substantially coplanar with the upper surfaces of each of the insulation layer 30 and the first conductive layer 32. According to an exemplary embodiment of the present inventive concept, on the second region R2, the upper surface of the insulation layer 30 may be substantially coplanar with the upper surface of the first conductive layer 32.

Through the processes discussed herein, the interposer substrate 100 may be provided having at least one through electrode 70 and at least one alignment key structure 80. The through electrode 70 may include the first conductive layer 32 formed on the insulation layer 30. The through electrode 70 may also include the second conductive layer 36 formed on the first conductive layer 32. According to an exemplary embodiment of the present inventive concept, the alignment key structure 80 may include the second opening 20, the insulation layer 30, and the first conductive layer 32. The insulation layer 30 may fill at least a portion of the second opening 20. The first conductive layer 31 may fill a remaining portion of the second opening 20.

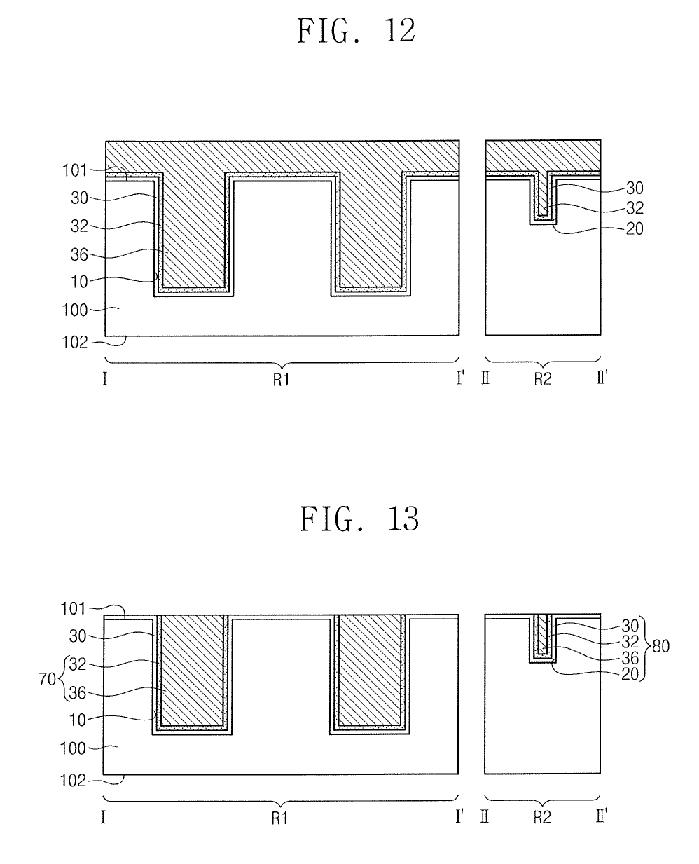

The alignment key structure 80 may be changed depending on the width of the second opening 20, which will be described in detail below with reference to FIGS. 12 to 15.

Referring to FIG. 12, the insulation layer 30, the first conductive layer 32, and the second conductive layer 36 may be sequentially formed on a structure of FIG. 9. On the first region R1, the insulation layer 30 and the first conductive layer 32 may each partially fill a portion of the first opening 10. The second conductive layer 36 may fill a remaining portion of the first opening 10 in which the insulation layer 30 and the first conductive layer 32 are formed. On the second region R2, the insulation layer 30 and the first conductive layer 32 may each partially fill a portion of the second opening 20. The second conductive layer 36 may fill a remaining portion of the second opening 20 in which the insulation layer 30 and the first conductive layer 32 are formed.

Referring to FIG. 13, a polishing process may be performed on the interposer substrate 100, for example, to expose the upper surface of the insulation layer 30. The alignment key structure 80 may include the second opening 20, the insulation layer 30, the first conductive layer 32, and the second conductive layer 36. The insulation layer 30 may fill at least a portion of the second opening 20. The first conductive layer 32 may fill at least another portion of the second opening 20. The second conductive layer 36 may fill a remaining portion of the second opening 20. According to an exemplary embodiment of the present inventive concept, on the second region R2, the upper surface of the insulation layer 30 may be substantially coplanar with the upper surfaces of each of the first and second conductive layers 32 and 36.

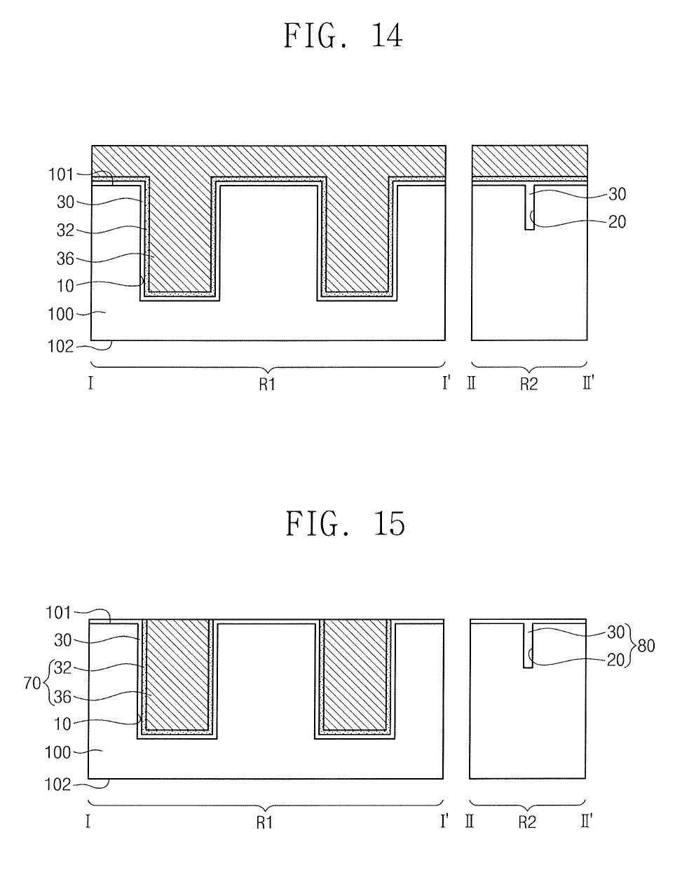

Referring to FIGS. 14 and 15, on the second region R2, the insulation layer 30 may be formed to fill the second opening 20. The first and second conductive layers 32 and 36 may be sequentially formed on the insulation layer 30. The second opening 20 may have a width less than about two times a thickness of the insulation layer 30. A polishing process may be performed to expose an upper surface of the insulation layer 30. The alignment key structure 80 may include the second opening 20 and the insulation layer 30. The insulation layer 30 may fill the second opening 20.

Referring to FIGS. 5 and 16, a routing layer 130 may be formed on a structure of FIG. 11. The routing layer 130 may include an interlayer dielectric layer 138, electrical line patterns 136, lower pads 132, and upper pads 134. The electrical line patterns 136 may be disposed in the interlayer dielectric layer 138.

The interlayer dielectric layer 138 may include, for example, silicon oxide, silicon nitride, and/or silicon oxynitride. The electrical line patterns 136 may include metal, for example, a material substantially the same as a material included in the second conductive layer 36.

The lower pads 132, the upper pads 134, and the electrical line patterns 136 may each be selectively disposed on the first region R1. The lower pads 132 may be electrically and/or physically connected to the through electrodes 70. The electrical line patterns 136 may be electrically and/or physically connected to the lower pads 132. The upper pads 134 may be electrically and/or physically connected to the electrical line patterns 136.

The upper and lower pads 134 and 132 may each include a conductive material. For example, the upper and lower pads 134 and 132 may each include substantially the same material as a material included in the electrical line patterns 136.

At least one of the upper pads 134 may be formed to have a size smaller than a size of the lower pads 132. The lower pads 132 may be more densely arranged as compared to the upper pads 134 and/or the through electrodes 70. For example, a spacing d1 between the upper pads 134 may be less than a spacing d2 between the lower pads 132. The spacing d1 between the upper pads 134 may also be less than a spacing d3 between the through electrodes 70. The electrical line patterns 136 may provide a redistribution pattern.

Referring to FIGS. 5 and 17, the interposer substrate 100 may be thinned, and interposer lower pads 112 may be formed. As the interposer substrate 100 is thinned, the interposer substrate 100 may have a lower surface 103. The through electrode 70 may be exposed through the lower surface 103. A lower portion of the interposer substrate 100 may be partially removed, for example, to expose portions of each of the insulation layer 30, the first conductive layer, and the second conductive layer 36. The lower surface 103 of the interposer substrate 100 may be substantially coplanar with each of the exposed lower surfaces of the insulation layer 30, the first conductive layer 32, and the second conductive layer 36.

The interposer lower pads 112 may be formed on an exposed lower surface of the through electrodes 70. The through electrodes 70 and the interposer lower pads 112 may be electrically and/or physically connected to each other. The interposer substrate 100 may be provided on a lower surface 103 thereof with an insulation layer 113. The interposer lower pads 112 may be exposed through the insulation layer 113. Alternatively, insulation layer 113 might not be formed on the lower surface 103 of the interposer substrate 100.

A dicing process may be performed on the interposer substrate 100. The dicing process may form a plurality of interposers 200. The dicing process may partially or completely remove the second region R2 of the interposer substrate 100. The alignment key structure 80 may be removed by the dicing process. Exemplary embodiments of the present inventive concept are not limited thereto. For example, at least a portion of the alignment key structure 80 might not be removed.

A method of manufacturing a semiconductor package according to exemplary embodiments of the present inventive concept will be discussed in more detail below with reference to FIG. 4.

Referring to FIG. 4, an interposer 200 may be provided. The interposer 200 may be formed by processes the same as or similar to those discussed with reference to FIGS. 5 to 17, and a detailed description thereof may be omitted.

A semiconductor chip 210 may be affixed to an upper surface of the interposer 200. Upper interconnect members 204 may be interposed between the semiconductor chip 210 and the upper pads 134 of the interposer 200. A thermal compression process and/or a reflow process may be performed, for example, to adhere the upper interconnect members 204 to each of the upper pads 134 of the interposer 200 and a lower side of the semiconductor chip 210. The upper interconnect members 204 may electrically connect the semiconductor chip 210 to the interposer 200.

A lower base substrate 190 may be affixed to a lower surface of the interposer 200. The lower base substrate 190 may include first pads 192 and second pads 194. The first pads 192 may be disposed on an upper surface of the lower base substrate 190. The second pads 194 may be disposed on a lower surface of the lower base substrate 190. The first pads 192 may be electrically connected to the second pads 194. External interconnect members 196 may be affixed to the lower surface of the lower base substrate 190. The external interconnect members 196 may be electrically and/or physically connected to the second pads 194.

Lower interconnect members 202 may be interposed between the first pads 192 of the lower base substrate 190 and the interposer lower pads 112 of the interposer 200. A thermal compression process and/or a reflow process may be performed, for example, to affix the lower interconnect members 202 to each of the first pads 192 of the lower base substrate 190 and the interposer lower pads 112 of the interposer 200. The interposer 200 may be electrically connected to the lower base substrate 190, for example, through the lower interconnect members 202.

According to an exemplary embodiment of the present inventive concept, an interposer substrate may be provided. The interposer substrate may have a photoresist pattern. The photoresist pattern may be in contact with an upper surface of the interposer substrate. An etching process may be performed on the interposer substrate using the photoresist pattern as an etch mask. Thus, undercuts produced in the interposer substrate during the etching process may be decreased or eliminated. Thus, a method of forming an interposer and a method of manufacturing a semiconductor package including the same having increased electrical characteristics and a relatively high process yield may be obtained.

Although exemplary embodiments of the present inventive concept have been described herein in connection with the accompanying drawings, it will be understood to those skilled in the art that various changes and modifications may be made without departing from the spirit and scope of the present invention.

What is claimed is:

1. A method of manufacturing a semiconductor package, comprising:
forming a photoresist pattern on a first surface of an interposer substrate, the interposer substrate including an electrode zone and a scribe line zone;
etching the interposer substrate using the photoresist pattern as a mask to form a first opening and a second opening respectively on the electrode zone and the scribe line zone; and
forming an insulation layer and a conductive layer on the first surface of the interposer substrate,
wherein a width of the second opening is smaller than a width of the first opening, and
wherein the insulation layer contacts each of the first surface of the interposer substrate, an inner surface of the first opening, and an inner surface of the second opening.

2. The method of claim 1, wherein the photoresist pattern comprises a third opening exposing a portion of the electrode zone corresponding to the first opening, and a fourth opening exposing a portion of the scribe line zone corresponding to the second opening,
wherein a width of the fourth opening is smaller than a width of the third opening.

3. The method of claim 1, wherein the conductive layer comprises a first conductive layer and a second conductive layer formed on the insulation layer,
wherein, the insulation layer and the first conductive layer are formed on the electrode zone and partially fill a portion of the first opening, and the second conductive layer fills a remaining portion of the first opening in which the insulation layer and the first conductive layer are formed.

4. The method of claim 3, wherein the insulation layer is formed on the scribe line zone and fills the second opening.

5. The method of claim 3, wherein the insulation layer is formed on the scribe line zone and partially fills a portion of the second opening, and the first conducive layer fills a remaining portion of the second opening in which the insulation layer is formed.

6. The method of claim 3, wherein the insulation layer and the first conductive layer are formed on the scribe line zone and partially fill a portion of the second opening, and the second conductive layer fills a remaining portion of the second opening in which the insulation layer and the first conductive layer are formed.

7. The method of claim 3, wherein the first conductive layer comprises a metal nitride layer, and the second conductive layer comprises a metal layer.

8. The method of claim 1, wherein a depth of the second opening is smaller than a depth of the first opening.

9. The method of claim 1, wherein the first and second conductive layers each include a through electrode, and
wherein the method further comprises:
forming a routing layer on the first surface of the interposer substrate, the routing layer being electrically connected to the through electrode;
partially removing a second surface of the interposer substrate to expose the through electrode, the second surface facing the first surface;
dicing the scribe line zone to form an interposer including the through electrode; and
affixing a semiconductor chip to an upper surface of the interposer, the semiconductor chip being electrically connected to the routing layer.

10. A method of forming an interposer, comprising:
forming a through electrode and an alignment key structure in a first region and a second region of an interposer substrate, respectively,
wherein forming the through electrode and the alignment key structure comprises:
forming a photoresist pattern on a first surface of the interposer substrate, the photoresist pattern being in contact with the first surface;
etching the interposer substrate using the photoresist pattern as a mask to form a first opening and a second opening, the through electrode being disposed in the first opening and the alignment key structure disposed in the second opening; and
forming an insulation layer, a first conductive layer, and a second conductive layer on the first surface of the interposer substrate,
wherein the insulation layer contacts each of the first surface of the interposer substrate, an inner surface of the first opening, and an inner surface of the second opening.

11. The method of claim 10, wherein,
a width of the first opening is larger than a width of the second opening, and
a depth of the first opening is larger than a depth of the second opening.

12. The method of claim 10, wherein,
the insulation layer and the first conductive layer are formed on the first region and partially fill a portion of the first opening, and the second conductive layer fills a remaining portion of the first opening in which the insulation layer and the first conductive layer are formed, and
the insulation layer is formed on the second region and fills the second opening.

13. The method of claim 10, wherein,
the insulation layer and the first conductive layer are formed on the first region and partially fill a portion of the first opening, and the second conductive layer fills a remaining portion of the first opening in which the insulation layer and the first conductive layer are formed, and
the insulation layer is formed on the second region and partially fills a portion of the second opening, and the first conducive layer fills a remaining portion of the second opening in which the insulation layer is formed.

14. The method of claim 10, wherein,
the insulation layer and the first conductive layer are formed on the first region and partially fill a portion of the first opening, and the second conductive layer fills a remaining portion of the first opening in which the insulation layer and the first conductive layer are formed, and
the insulation layer and the first conductive layer are formed on the second region and partially fill a portion of the second opening, and the second conductive layer fills a remaining portion of the second opening in which the insulation layer and the first conductive layer are formed.

15. The method of claim 10, wherein the first region is a plurality of first regions, and the second region separates the first regions from each other, and
wherein the method further comprises:
forming a routing layer on the first surface of the interposer substrate, the routing layer being electrically connected to the through electrode;
partially removing a second surface of the interposer substrate to expose the through electrode, the second surface facing the first surface; and
dicing the second region to separate the first regions from each other.

16. A method of manufacturing a semiconductor package, comprising:
forming a photoresist pattern on an interposer substrate, the interposer substrate including a first area and a second area;
forming a first opening on the first area and a second opening on the second area by etching the interposer substrate using the photoresist pattern as a mask; and
forming an insulation layer on the interposer substrate,
wherein the insulation layer contacts each of the interposer substrate, the first opening, and the second opening.

17. The method of claim 16, wherein the method further comprises forming a conductive layer on the interposer substrate.

18. The method of claim 16, wherein the photoresist pattern comprises a third opening exposing a portion of the first area corresponding to the first opening, and a fourth opening exposing a portion of the second area corresponding to the second opening,
wherein a width of the fourth opening is smaller than a width of the third opening.

19. The method of claim 16, wherein the insulation layer contacts an upper surface of the interposer substrate, an inner surface of the first opening, and an inner surface of the second opening.

20. The method of claim 16, wherein a depth of the second opening is smaller than a depth of the first opening.
